(19) United States
(12) Patent Application Publication
(10) Pub. No.: US 2005/0112892 A1
(43) Pub. Date: May 26, 2005

(54) Chemical mechanical abrasive slurry and method of using the same

(75) Inventors: Pao Cheng Chen, Kaohsiung (TW); Tsung Ho Lee, Kaohsiung (TW); Wen Cheng Liu, Kaohsiung (TW)

Correspondence Address: SCULLY SCOTT MURPHY & PRESSER, PC, 400 GARDEN CITY PLAZA, SUITE 300, GARDEN CITY, NY, 11530, US

(73) Assignee: Eternal Chemical Co., Ltd., Kaohsiung (TW)

(21) Appl. No.: 10/867,476

(22) Filed: Jun. 14, 2004

(30) Foreign Application Priority Data
Nov. 20, 2003 (TW) 092132592

(51) Int. Cl. H01L 21/302; H01L 21/461

(52) U.S. Cl. 438/692

(57) ABSTRACT

The invention provides a chemical mechanical abrasive slurry for use in semiconductor processing. The slurry comprises composite abrasive particles consisting of substrate particles coated with alumina. The invention further relates to a chemical mechanical polishing method of using said slurry in polishing the surfaces of semiconductor wafers.

### TECHNICAL FIELD

The invention relates to a chemical mechanical abrasive slurry that is effective in polishing the surfaces of semiconductor wafers.

### BACKGROUND ART

Chemical mechanical polishing (CMP) is a planarization technique which was developed to address the problem associated with the difficulty in focus during a photolithography process for producing integrated circuits owing to the difference in the height of deposited films. Chemical mechanical polishing technique was first applied to the production of the elements with a size in the order of 0.5 microns. With the reduction in the size of elements, the chemical mechanical polishing technique was applicable to an increased number of layers. Until the elements were developed to the order of 0.25 microns, the chemical mechanical polishing became a main and essential planarization technique. In general, the polishing method for producing a wire circuit comprises mounting a semiconductor wafer on a spinning platen equipped with an abrasive head and applying an abrasive slurry comprising abrasive particles and an oxidant to the surface of the wafer to enhance the abrasion efficacy.

There are a number of patent documents that have disclosed using abrasive slurries in polishing metal layers on semiconductor wafers. For example, U.S. Pat. No. 5,225,034 discloses a chemical mechanical abrasive slurry which comprises AgNO₃, solid abrasive particles, and an oxidant selected from H₂O₂, HOCl, KOCl, KMgO₄, or CH₃COOOH. The slurry is used for polishing a copper layer on a semiconductor wafer so as to produce a copper wire on the wafer.

U.S. Pat. No. 5,084,071 discloses a chemical mechanical polishing slurry for an electronic component substrate. The polishing slurry comprises no more than 1 weight percent of alumina, abrasive particles (e.g. SiO₂, CeO₂, SiC, Si₃N₄, or Fe₂O₃ particles), a transition metal chelated salt (e.g. ammonium iron EDTA) for use as a polishing accelerator, and a solvent for said salt.

U.S. Pat. No. 5,336,542 discloses a polishing composition comprising alumina abrasive particles and a chelating agent selected from the group consisting of polyaminocarboxylic acid (e.g. EDTA) and sodium and potassium salts thereof.

Normally, the abrasive slurries proposed in the above patents would suffer from the problems associated with the precipitation of the abrasive particles contained in the slurries and could not meet the requirements of higher removal rates and lower dishing values for new-age polishing.

In addition, during the copper processing, the copper film will be subjected to an annealing treatment and a dense copper oxide layer will be formed on the copper film. Moreover, unneeded copper often remains on the wafers when part of the copper on the wafers has been removed and dishings began to appear because of the unevenness problems associated with the CMP processing. Thus, it is essential for CMP processing to find solutions which could rapidly remove copper residue so as to reduce the copper wire dishing and to promote the production capacity.

Ta and TaN are two major barrier layer materials currently used in copper processing. The selectivity of an abrasive agent to copper metal relative to barrier layer is very critical in the step for removing copper metal if said barrier layer serves as an abrasion stop layer. As a result of the further thinning of barrier layer in advanced processing, there is a need for abrasive slurries which exhibit a higher selectivity as so to facilitate the operation of processing.

The inventors of the invention have found, through extensive research, that an abrasive slurry comprising composite abrasive particles may prevent the precipitation of abrasive particles, effectively enhance the selectivity ratio of the metal layer to TaN, and further prevent the formation of copper dishing, and thus will effectively avoid the above-mentioned disadvantages encountered by chemical mechanical abrasive slurries.

### SUMMARY OF THE INVENTION

One object of the invention is to provide a chemical mechanical abrasive slurry for use in semiconductor processing, characterized in that it comprises composite abrasive particles, wherein said composite abrasive particles consist of substrate particles coated with alumina.

Another object of the invention is to provide a chemical mechanical abrasive slurry for polishing the surfaces of semiconductor wafers, which comprises an aqueous medium, a surfactant and abrasive particles, characterized in that said abrasive particles are composite abrasive particles consisting of substrate particles coated with alumina.

Still another object of the invention is to provide a chemical mechanical abrasion method for polishing the surfaces of semiconductor wafers using the inventive slurry.

### DETAILED DESCRIPTION OF THE INVENTION

The invention provides a chemical mechanical abrasive slurry for use in semiconductor processing, characterized in that it comprises composite abrasive particles. Said composite abrasive particles consist of substrate particles coated with alumina and said substrate particles are selected from the group consisting of SiO₂, ZrO₂, CeO₂, SiC, Fe₂O₂, TiO₂ and Si₃N₄ and mixtures thereof, preferably SiO₂.

The amount of the composite abrasive particles used in the invention, based on the total weight of the abrasive slurry, is in the range from 0.1 to 29 wt %, preferably 0.5 to 5wt %.

The invention further provides a chemical mechanical abrasive slurry for polishing the surfaces of semiconductor wafers, which comprises an aqueous medium, a surfactant and an abrasive material, wherein said abrasive material comprises composite abrasive particles which consists of substrate particles coated with alumina. The amount of the aqueous medium, based on the total weight of the abrasive slurry, is in the range from 70 to 99.5 wt %, preferably 90 to 99.5 wt %, and more preferably 95 to 99.5 wt %. The amount of the surfactant is in the range from 0.01 to 3.0 wt %, preferably from 0.05 to 1.0 wt %. The amount of the composite abrasive particles is in the range from 0.1 to 29 wt %, preferably from 0.5 to 5 wt %.

The aqueous medium which may be used in the invention is apparent to those skilled in the art. For example, water; preferably deionized water can be used in the preparation of the slurry.

The surfactant used in the invention may be an anionic surfactant.

The abrasive slurry may optionally contain an oxidant and corrosion inhibitor. The use of such additives is well known to those skilled in the art. There is no special limitation for the oxidant. Examples of the oxidant include but not limited to H₂O₂, Fe(NO₃)₃, KIO₃, CH₃COOOH and KMnO₄, preferably H₂O₂. The corrosion inhibitor applicable to the invention is a triazole compound, which may be selected from benzotriazole, cyanuric acid (1,3,5-triazine-2,4,6-triol), 1,2,3-triazole, 3-amino-1,2,4- triazole, 3-nitro-1,2,4-triazole, purpald®, benzotriazole-5-carboxylic acid, 3-amino-1,2,4-triazole-5-carboxylic acid, 1-hydroxy benzotriazole or nitro benzotriazole, preferably benzotriazole. The chemical mechanical abrasive slurry of the invention may comprise, based on the total weight of the abrasive slurry, from 0.1 to 5 wt % of the oxidant and from 0.01 to 1 wt % corrosion inhibitor.

The abrasive slurry of the invention may also include other components which are well known in chemical mechanical abrasive art and will not cause any adverse influences on the abrasive composition of the invention. For example, an organic acid can be added to enhance chelation or a base or an acid, such as aqueous ammonia or nitric acid, can be added to adjust the pH value. Suitable organic acids, among others, include but not limited to formic acid, acetic acid, propanoic acid, butyric acid, valeric acid, hexanoic acid, malonic acid, glutaric acid, adipic acid, phosphorous acid, oxalic acid, citric acid, malic acid and tartaric acid.

As illustrated by the following examples, the abrasive slurry of the invention can increase the selectivity ratio of metal copper to TaN and thus may avoid the generation of copper dishing.

The invention further relates to a method for polishing the surfaces of semiconductor wafers comprising applying the chemical mechanical abrasive slurry of the invention to the surfaces of said wafers and polishing the metal layer on the surfaces of the semiconductor wafers using said slurry. Typically, the metal layer described above is copper.

The invention will be further described in detail by the following examples which are descriptive and not limiting the scope of the invention. Any modifications and changes easily achieved by those skilled in the art are within the scope of the invention and the attached claims.

### EXAMPLES

Polishing Test
A. Instrument: AMAT/Mirra
B. Conditions: Membrane Pressure: 2 psi
   Inner Tube: Vent
   Retaining Ring: 2.6 psi
   Platen Speed: 93 rpm
   Carrier Speed: 87 rpm
   Temperature: 25° C.
   Pad Type: IC1000, k-x y.
   Slurry Velocity: 150 ml/min.
C. Wafer: Patterned Wafer, commercially available from Sematech, Type: 0.25 μm line width 854CMP017 wafer.
D. Slurry: The abrasive slurries illustrated in the examples, each of which further contains 3.0 wt % H₂O₂.
   Procedure of Polishing Test

The invention used Mirra polishing machine of Applied Materials for polishing. The signal obtained from End Point System was configured as EP2 signal for the polishing procedure. During polishing, 20% over-polishing was conducted after the polishing with each of the abrasive slurries shown in the examples reached EP2. The wafers were cleaned by Evergreen Model 10× Cleaner of Solid State Equipment Corporation after polishing and then dried with N₂. KLA-Tencor P-11 Surface Profiler was then used to measure the level of the copper dishing. Copper wire with a width of 100 μm was used as the measuring reference point and its dishing relative to that of the barrier layer was measured.

### Example 1

Colloidal silica was used as abrasive particles.

The resultant abrasive slurry has the following composition:
Colloidal silica: 3.0 wt %;
Benzotriazole (BTA): 0.1 wt %;
Phosphorous acid: 0.2 wt %;
Surfynol CT-161: 0.1 wt %;
Balance: aqueous ammonia or nitric acid for adjusting pH value and deionized water.
Results of the polishing test are shown in Table 1.

### Example 2

A slurry having a composition similar to Example 1 was prepared, except that the abrasive particles were changed to alumina. Results of the polishing test are shown in Table 1.

### Example 3

A slurry having a composition similar to Example 2 was prepared, except that the pH value was changed to be in the range of from 5 to 6.

### Example 4

A slurry having a composition similar to Example 2 was prepared, except that the alumina abrasive particles were changed to 3 wt % composite abrasive particles. The composite abrasive particles used in this Example are colloidal silica particles coated with alumina. Results of the polishing test are shown in Table 1.

### Example 5

A slurry having a composition similar to Example 4 was prepared, except that the pH value was changed to be in the range of from 5 to 6.

### Example 6

A slurry having a composition similar to Example 4 was prepared, except that the weight percentage of the composite abrasive particles was changed to 1 wt %.

### Example 7

A slurry having a composition similar to Example 4 was prepared, except that the concentration of phosphorous acid was increased from 0.2 wt % to 0.5 wt %. Results of the polishing test are shown in Table 1.

### Example 8

A slurry having a composition similar to Example 4 was prepared, except that adipic acid was used instead of phosphorous acid. Results of the polishing test are shown in Table 1.

### Example 9

A slurry having a composition similar to Example 4 was prepared, except that formic acid was used instead of phosphorous acid. Results of the polishing test are shown in Table 1.

### Example 10

A slurry having a composition similar to Example 4 was prepared, except that the composite abrasive particles were changed to cerium oxide (CeO₂) particles coated with alumina. Results of the polishing test are shown in Table 1.

TABLE 1

| | | | | | | | Dishing |
|---|---|---|---|---|---|---|---|
| | | | | | Cu | TaN | (Å/100 μm |
| | | Solids | | | removal | removal | Cu |
| | | Content | Chemical added and | | rate | rate | line |
| Ex. | Abrasive particles | (%) | the content (wt. %) | pH | (Å/min) | (Å/min) | width) |
| 1 | Colloidal silica | 3 | Phosphorous acid (0.2%) | 3-4 | 4768 | 172 | 1677 |
| | | | surfynol CT-161(0.1%) | | | | |
| 2 | Alumina | 3 | Phosphorous acid (0.2%) | 3-4 | Chemicals subsided and | | |
| | | | surfynol CT-161(0.1%) | | polishing could not be carried | | |
| | | | | | out | | |
| 3 | Alumina | 3 | Phosphorous acid (0.2%) | 5-6 | 4848 | 33 | 836 |
| | | | surfynol CT-161(0.1%) | | | | |
| 4 | Composite abrasive | 3 | Phosphorous acid | 3-4 | 7960 | 14 | 238 |
| | particles | | (0.2%) | | | | |
| | (colloidal silica coated with | | surfynol CT-161(0.1%) | | | | |
| | alumina) | | | | | | |
| 5 | Composite abrasive | 3 | Phosphorous acid | 5-6 | 5883 | 25 | 343 |
| | particles | | (0.2%) | | | | |
| | (colloidal silica coated with | | surfynol CT-161(0.1%) | | | | |
| | alumina) | | | | | | |
| 6 | Composite abrasive | 1 | Phosphorous acid | 3-4 | 6967 | 12 | 187 |
| | particles | | (0.2%) | | | | |
| | (colloidal silica coated with | | surfynol CT-161(0.1%) | | | | |
| | alumina) | | | | | | |
| 7 | Composite abrasive | 3 | Phosphorous acid | 3-4 | 7225 | 14 | 268 |
| | particles | | (0.5%) | | | | |
| | (colloidal silica coated with | | surfynol CT-161(0.1%) | | | | |
| | alumina) | | | | | | |
| 8 | Composite abrasive | 3 | Adipic acid (0.2%) | 3-4 | 7648 | 16 | 257 |
| | particles | | surfynol CT-161(0.1%) | | | | |
| | (colloidal silica coated with | | | | | | |
| | alumina) | | | | | | |
| 9 | Composite abrasive | 3 | Formic acid (0.2%) | 3-4 | 7430 | 16 | 262 |
| | particles | | surfynol CT-161(0.1%) | | | | |
| | (colloidal silica coated with | | | | | | |
| | alumina) | | | | | | |
| 10 | Composite abrasive | 3 | Phosphorous acid (0.2%) | 3-4 | 6845 | 23 | 287 |
| | particles | | surfynol CT-161(0.1%) | | | | |
| | (Cerium oxide coated | | | | | | |
| | with alumina) | | | | | | |

Note:
Surfynol CT-161 is an anionic surfactant produced by Air Products Corp.

The results of Examples 1 to 3 show that alumina abrasive particles achieve higher removal rate and better abrasive selectivity ratio than colloidal silica and perform better in preventing copper dishing with the only disadvantage being that the slurry is less stable and easy to subside.

The results of Examples 1 to 4 show that composite abrasive particles are more stable in slurry and can increase selectivity ratio and prevent copper dishing, as compared with single component abrasive particles.

The results of Examples 4 and 5 show that the slurries of different pH values are applicable to the abrasive system of the invention.

The results of Examples 4 and 6 show that the slurries containing composite particles with different solids contents are applicable to the abrasive system of the invention and can increase selectivity ratio and prevent copper dishing.

The results of Examples 4 and 7 show that adding phosphorous acid at different concentrations to the abrasive slurries is suitable for the abrasive system of the invention and can increase selectivity ratio and prevent copper dishing.

The results of Example 4, Example 8, and Example 9 show that adding different acids to the abrasive slurry is suitable for the abrasive system of the invention and can increase selectivity ratio and prevent copper dishing.

The results of Examples 4 and 10 show that the slurries of composite particles having different substrate materials are applicable to the abrasive system of the invention and can increase selectivity ratio and prevent copper dishing.

1. A chemical mechanical abrasive slurry, characterized in that it comprises composite abrasive particles consisting of substrate particles coated with alumina.

2. The chemical mechanical abrasive slurry of claim 1, wherein the substrate particles are selected from the group consisting of SiO₂, ZrO₂, CeO₂, SiC, Fe₂O₂, TiO₂, Si₃N₄ and mixtures thereof.

3. A chemical mechanical abrasive slurry for polishing the surfaces of semiconductor wafers, said slurry comprising an aqueous medium, a surfactant, and abrasive particles, characterized in that said abrasive particles are composite abrasive particles consisting of substrate particles coated with alumina.

4. The chemical mechanical abrasive slurry of claim 3 comprising, based on the total weight of the abrasive slurry, 70-99.5 wt % of said aqueous medium, 0.01-3.0 wt % of said surfactant, and 0.1-29 wt % of said composite abrasive particles.

5. The chemical mechanical abrasive slurry of claim 4, wherein the content of the aqueous media is 95-99.5 wt %.

6. The chemical mechanical abrasive slurry of claim 4, wherein the content of the surfactant is 0.05-1.0 wt %.

7. The chemical mechanical abrasive slurry of claim 4, wherein the content of the composite abrasive particles is 0.5-5 wt %.

8. The chemical mechanical abrasive slurry of claim 4, wherein the surfactant is an anionic surfactant.

9. The chemical mechanical abrasive slurry of claim 4, wherein the substrate particles are selected from the group consisting of SiO₂, ZrO₂, CeO₂, SiC, Fe₂O₂, TiO₂, Si₃N₄ and mixtures thereof.

10. The chemical mechanical abrasive slurry of claim 4 further comprising, based on the total weight of the abrasive slurry, 0.1-5 wt % of an oxidant and 0.01-1 wt % of a corrosion inhibitor.

11. The chemical mechanical abrasive slurry of claim 10, wherein said oxidant is selected from the group consisting of H₂O₂, Fe(NO₃)₃, KIO₃, CH₃COOOH and KMnO₄ and said corrosion inhibitor is a triazole compound.

12. A method for polishing the surfaces of semiconductor wafers comprising applying the chemical mechanical abrasive slurry according to any of claims 1 to 11 to the surfaces of the wafers and polishing the metal layer on the surfaces of the semiconductor wafers by said abrasive slurry.

13. The method of claim 12, wherein the metal layer is copper.
